(19) United States
(12) Patent Application Publication
(10) Pub. No.: US 2026/0130091 A1
(43) Pub. Date: May 7, 2026

(54) DISPLAY DEVICE, DISPLAY SYSTEM INCLUDING DISPLAY DEVICE, AND METHOD OF FABRICATING DISPLAY DEVICE

(71) Applicant: Samsung Display Co., LTD., Yongin-si (KR)

(72) Inventors: Hee Min PARK, Yongin-si (KR); A Rong KIM, Yongin-si (KR); Jae Ik KIM, Yongin-si (KR); Young Min MOON, Yongin-si (KR); Hee Jun YANG, Yongin-si (KR); Sa Min LEE, Yongin-si (KR); Won Je CHO, Yongin-si (KR)

(21) Appl. No.: 19/284,984

(22) Filed: Jul. 30, 2025

(30) Foreign Application Priority Data
Nov. 1, 2024 (KR) 10-2024-0153755

(51) Int. Cl. H10K 59/80; H10K 59/12; H10K 59/122; H10K 102/00

(52) U.S. Cl. CPC H10K 59/80523; H10K 59/1201; H10K 59/122; H10K 59/80515; H10K 59/80521; H10K 59/80524; H10K 2102/351

(57) ABSTRACT

A display device includes: a substrate on which first to third sub-pixels are defined; sidewalls disposed on the substrate; an anode electrode disposed on the substrate to correspond to the first to third sub-pixels; a first emission structure disposed on the anode electrode of the first sub-pixel; a second emission structure disposed on the anode electrode of the second sub-pixel; a third emission structure disposed on the anode electrode of the third sub-pixel; a cathode electrode disposed on the first emission structure, the second emission structure, and the third emission structure; and a capping layer disposed on the cathode electrode. Each of the sidewalls includes: a first sidewall; and a second sidewall disposed on the first sidewall, and having a width greater than a width of the first sidewall. The capping layer does not overlap at least one of the first to third emission structures in a plan view.

This application claims priority to Korean Patent Application No. 10-2024-0153755, filed on Nov. 1, 2024, and all the benefits accruing therefrom under 35 U.S.C. § 119, the content of which in its entirety is herein incorporated by reference.

### BACKGROUND

### (1) Field

Various embodiments of the disclosure relate to a display device, a display system including the display device, and a method of fabricating the display device.

### (2) Description of the Related Art

With the development of information technology, the importance of display devices as a medium which connects users and information has become increasingly emphasized. Accordingly, research and development on display devices have been continuously conducted.

Organic light emitting diodes (OLEDs) are active emission display elements which are characterized by a wide viewing angle, high contrast, low-voltage operation, and relatively high response speed.

Display devices may include a plurality of layers, and light emitted from the OLEDs may pass through the plurality of layers and be provided outward. Accordingly, the plurality of layers included in the display device may change optical characteristics of the emitted light.

### SUMMARY

Embodiments of the disclosure are directed to a display device with improved light efficiency and lifespan, a display system including the display device, and a method of fabricating the display device.

Embodiments of the disclosure are directed to a method of fabricating a display device capable of facilitating a fabrication process.

An embodiment of the present disclosure provides a display device, including: a substrate on which a first sub-pixel, a second sub-pixel, and a third sub-pixel are defined; sidewalls disposed on the substrate; an anode electrode disposed on the substrate to correspond to each of the first sub-pixel, the second sub-pixel, and the third sub-pixel; a first emission structure disposed on the anode electrode of the first sub-pixel; a second emission structure disposed on the anode electrode of the second sub-pixel; a third emission structure disposed on the anode electrode of the third sub-pixel; a cathode electrode disposed on the first emission structure, the second emission structure, and the third emission structure; and a capping layer disposed on the cathode electrode. In such an embodiment, each of the sidewalls includes: a first sidewall; and a second sidewall disposed on the first sidewall, and having a width greater than a width of the first sidewall. In such an embodiment, the capping layer does not overlap at least one of the first emission structure, the second emission structure, and the third emission structure in a plan view.

In an embodiment, the display device may include a pixel defining layer disposed under the sidewalls. In such an embodiment, the pixel defining layer may exposes at least a portion of the anode electrode. In such an embodiment, the sidewalls may be respectively located in areas between the first emission structure, the second emission structure, and the third emission structure.

In an embodiment, the anode electrode may be disposed on the sidewalls.

In an embodiment, the display device may further include a pixel defining layer which encloses the anode electrode. In such an embodiment, the pixel defining layer may be disposed on the second sidewall. In such an embodiment, the anode electrode may have a surface area smaller than a surface area of the second sidewall in a plan view.

In an embodiment, the cathode electrode may include: a first cathode electrode which contacts the first emission structure, the second emission structure, and the third emission structure; and a second cathode electrode disposed on the first cathode electrode.

In an embodiment, the second cathode electrode may include a transparent conductive oxide (TCO). In such an embodiment, the second cathode electrode may enclose the second sidewall.

In an embodiment, the capping layer may have a first transmittance and a first refractive index with respect to light in a visible light range. In such an embodiment, the second cathode electrode may have a second transmittance and a second refractive index with respect to the light in the visible light range. In such an embodiment, the first transmittance may be in a range from 0.9 times to 1.1 times the second transmittance. In such an embodiment, the first refractive index may be in a range from 0.9 times to 1.1 times the second refractive index.

In an embodiment, the capping layer may not overlap one of the first emission structure, the second emission structure, and the third emission structure in the plan view, and may overlap remaining two of the first emission structure, the second emission structure, and the third emission structure in the plan view.

In an embodiment, the capping layer may not overlap two of the first emission structure, the second emission structure, and the third emission structure in the plan view, and may overlap a remaining one of the first emission structure, the second emission structure, and the third emission structure in the plan view.

In an embodiment, the display device may further include an encapsulation layer disposed on the capping layer. In such an embodiment, the capping layer may contact the encapsulation layer.

In an embodiment, the first sub-pixel may provide light in a wavelength range from about 600 nanometers (nm) to about 750 nm. In such an embodiment, the second sub-pixel may provide light in a wavelength range from about 480 nm to about 560 nm. In such an embodiment, the third sub-pixel may provide light in a wavelength range from 370 nm to 460 nm. In such an embodiment, in the plan view, the capping layer may overlap the first emission structure and the second emission structure, and may not overlap the third emission structure. In such an embodiment, each of the first emission structure, the second emission structure, and the third emission structure may include an organic emission material.

An embodiment of the present disclosure provides a display device, including: a substrate on which a first sub-pixel, a second sub-pixel, and a third sub-pixel are defined; sidewalls disposed on the substrate; an anode electrode disposed on the substrate to correspond to each of the first sub-pixel, the second sub-pixel, and the third sub-pixel; a first emission structure disposed on the anode electrode of the first sub-pixel; a second emission structure disposed on the anode electrode of the second sub-pixel; a third emission structure disposed on the anode electrode of the third sub-pixel; and a cathode electrode disposed on the first emission structure, the second emission structure, and the third emission structure. In such an embodiment, each of the sidewalls includes: a first sidewall; and a second sidewall disposed on the first sidewall, and having a width greater than a width of the first sidewall. In such an embodiment, the cathode electrode includes: a first cathode electrode which contacts the first emission structure, the second emission structure, and the third emission structure; and a second cathode electrode disposed on the first cathode electrode. In such an embodiment, portions of the second cathode electrode, which respectively overlap the first emission structure, the second emission structure and the third emission structure, have different thicknesses from each other.

In an embodiment, the display device may further include an encapsulation layer disposed on the second cathode electrode. In such an embodiment, the second cathode electrode may contact the encapsulation layer.

In an embodiment, the display device may further include a pixel defining layer disposed under the sidewalls. In such an embodiment, the pixel defining layer may expose at least a portion of the anode electrode. In such an embodiment, the sidewalls may be respectively located in areas between the first emission structure, the second emission structure, and the third emission structure.

In an embodiment, the display device may further include a pixel defining layer which encloses sides of the anode electrode. In such an embodiment, the anode electrode and the pixel defining layer may be disposed on the second sidewall. In such an embodiment, the anode electrode may have a surface area smaller than a surface area of the second sidewall in a plan view.

An embodiment of the present disclosure provides a method of fabricating a display device, including: forming sidewalls on a substrate on which a first sub-pixel area, a second sub-pixel area, and a third sub-pixel area are defined; forming a first light emitting element on the substrate in the first sub-pixel area; forming a second light emitting element on the substrate in the second sub-pixel area; forming a third light emitting element on the substrate in the third sub-pixel area; and forming a capping layer on at least one selected from the first light emitting element, the second light emitting element, and the third light emitting element. In such an embodiment, the forming the first light emitting element includes forming a first emission structure. In such an embodiment, the forming the second light emitting element includes forming a second emission structure. In such an embodiment, the forming the third light emitting element includes forming a third emission structure. In such an embodiment, the first emission structure, the second emission structure, and the third emission structure are respectively formed through different processes. In such an embodiment, each of the sidewalls includes: a first sidewall; and a second sidewall disposed on the first sidewall, and having a width greater than a width of the first sidewall. In such an embodiment, the capping layer overlaps the at least one selected from the first light emitting element, the second light emitting element, and the third light emitting element in a plan view.

In an embodiment, each of the forming the first light emitting element, the forming the second light emitting element, and the forming the third light emitting element may include forming a cathode electrode. In such an embodiment, the cathode electrode may include: a first cathode electrode which contacts the first emission structure, the second emission structure, and the third emission structure; and a second cathode electrode disposed on the first cathode electrode. In such an embodiment, in the plan view, the capping layer may overlap one or two of the first emission structure, the second emission structure, and the third emission structure.

In an embodiment, the method may further include forming anode electrodes on the substrate. In such an embodiment, the anode electrodes may be disposed on the sidewalls.

An embodiment of the present disclosure provides a display system including: a processor; and a display device including pixels, where the display device displays images on the pixels under control of the processor. In such an embodiment, the display device includes: a substrate on which a first sub-pixel, a second sub-pixel, and a third sub-pixel are defined; sidewalls disposed on the substrate; an anode electrode disposed on the substrate to correspond to each of the first sub-pixel, the second sub-pixel, and the third sub-pixel; a first emission structure disposed on the anode electrode of the first sub-pixel; a second emission structure disposed on the anode electrode of the second sub-pixel; a third emission structure disposed on the anode electrode of the third sub-pixel; a cathode electrode disposed on the first emission structure, the second emission structure, and the third emission structure; and a capping layer disposed on the cathode electrode. In such an embodiment, each of the sidewalls includes: a first sidewall; and a second sidewall disposed on the first sidewall, and having a width greater than a width of the first sidewall. In such an embodiment, the capping layer does not overlap at least one of the first emission structure, the second emission structure, and the third emission structure in a plan view.

An embodiment of the present disclosure may provide a display system, including: a processor; and a display device including pixels, which displays images on the pixels under control of the processor. In such an embodiment, the display device includes: a substrate on which a first sub-pixel, a second sub-pixel, and a third sub-pixel are defined; sidewalls disposed on the substrate; an anode electrode disposed on the substrate to correspond to each of the first sub-pixel, the second sub-pixel, and the third sub-pixel; a first emission structure disposed on the anode electrode of the first sub-pixel; a second emission structure disposed on the anode electrode of the second sub-pixel; a third emission structure disposed on the anode electrode of the third sub-pixel; and a cathode electrode disposed on the first emission structure, the second emission structure, and the third emission structure. In such an embodiment, each of the sidewalls may include: a first sidewall; and a second sidewall disposed on the first sidewall, and having a width greater than a width of the first sidewall. In such an embodiment, the cathode electrode includes: a first cathode electrode which contacts the first emission structure, the second emission structure, and the third emission structure; and a second cathode electrode disposed on the first cathode electrode. In such an embodiment, portions of the second cathode electrode, which respectively overlap the first emission structure, the second emission structure, and the third emission structure, have different thicknesses from each other.

### BRIEF DESCRIPTION OF THE DRAWINGS

FIG. 1 is a schematic plan view illustrating a display device in accordance with an embodiment.

FIG. 2 is a schematic exploded perspective view illustrating the display device in accordance with an embodiment.

FIG. 3 is a plan view illustrating an embodiment of any one of pixels of FIG. 2.

FIG. 4 is a plan view illustrating another embodiment of one of the pixels of FIG. 2.

FIG. 5 is a plan view illustrating another embodiment of one of the pixels of FIG. 2.

FIG. 6 is a schematic sectional view illustrating the display device in accordance with an embodiment.

FIG. 7 is a schematic sectional view illustrating an emission structure in accordance with an embodiment.

FIG. 8 is a schematic sectional view illustrating the display device in accordance with an embodiment.

FIG. 9 is a graph illustrating experimental results of relative light efficiency for respective sub-pixels in accordance with an embodiment.

FIG. 10 is a schematic sectional view illustrating a cathode electrode and an encapsulation layer in accordance with an embodiment.

FIG. 11 is a flowchart illustrating a method of fabricating the display device in accordance with an embodiment.

FIG. 12 is a block diagram illustrating an embodiment of a display system.

FIG. 13 is a perspective diagram illustrating an application example of the display system of FIG. 12.

FIG. 14 is a diagram illustrating a head-mounted display device of FIG. 13 that is worn on a user.

FIG. 15 is a block diagram illustrating an embodiment of a display system including the display device of FIG. 1.

FIG. 16 is a perspective view illustrating an example of a smartphone which can be implemented using the display system of FIG. 15.

FIG. 17 is a perspective view illustrating an example of a tablet computer which can be implemented using the display system of FIG. 15.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Various embodiments of the disclosure relate to a display device, a display system including the display device, and a method of fabricating the display device. Hereinafter, a display device, a display system including the display device, and a method of fabricating the display device in accordance with embodiments will be described with reference to the accompanying drawings.

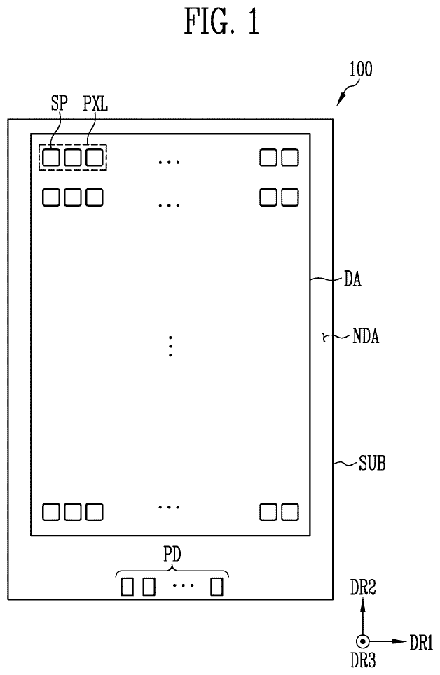

FIG. 1 is a schematic plan view illustrating a display device 100 in accordance with an embodiment.

Referring to FIG. 1, the display device 100 in accordance with an embodiment is configured to emit light.

The display device 100 may include a display area DA and a non-display area NDA. The display device 100 may display an image through the display area DA. The non-display area NDA may be defined or formed around the display area DA.

The display device 100 may include a substrate SUB, sub-pixels SP, and pads PD.

The display device 100 may be applied to various types of electronic device. In an embodiment, for example, the display device 100 may be used to provide a display screen of a device, such as a head-mounted display (HMD), a virtual reality (VR) device, a mixed reality (MR) device, or an augmented reality (AR) device. In such an embodiment, the display device 100 may be positioned very close to the eyes of a user, such that relatively high-density sub-pixels SP may be desired. To increase the pixel density of the sub-pixels SP, the substrate SUB may be provided using a silicon substrate. The sub-pixels SP and/or the display device 100 may be formed on the substrate SUB, which is a silicon substrate. The display device 100 fabricated based on the substrate SUB, which is a silicon substrate, may be referred to as an OLED on Silicon (OLEDoS) display device.

The sub-pixels SP may be disposed in the display area DA on the substrate SUB. The sub-pixels SP may be arranged in a matrix form in a first direction DR1 and a second direction DR2 crossing the first direction DR1. However, the embodiments are not limited to the aforementioned example. In an embodiment, for example, the sub-pixels SP may be arranged in a zigzag pattern in the first direction DR1 and the second direction DR2. In an embodiment, for example, the sub-pixels SP may be arranged in a PENTILE™ pattern. The first direction DR1 may refer to a row direction, and the second direction DR2 may refer to a column direction. A third direction DR3 may be perpendicular to the first direction DR1 and the second direction DR2 and, depending on the embodiment, the third direction DR3 may correspond to a thickness direction of the substrate SUB or a light output direction of the display device 100.

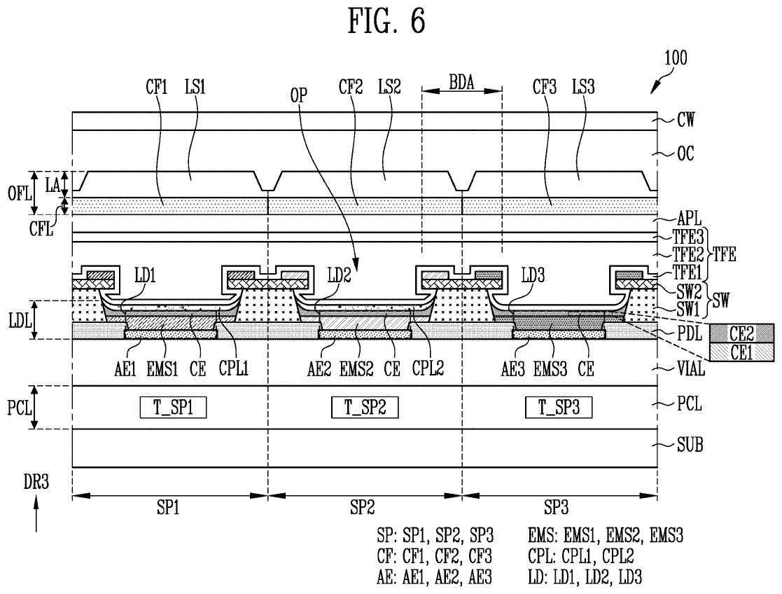

Each of the sub-pixels SP may include at least one light emitting element LD (refer to FIG. 6) configured to generate light. Accordingly, each of the sub-pixels SP may generate light in a specific color such as red, green, blue, cyan, magenta, or yellow. Two or more sub-pixels SP among the sub-pixels SP may form one pixel PXL. In an embodiment, for example, as illustrated in FIG. 1, three sub-pixels SP may form one pixel PXL.

Hereinafter, descriptions will be provided based on an embodiment where the sub-pixels SP include a first sub-pixel SP1 which provides light of a first color (e.g., red), a second sub-pixel SP2 which provides light of a second color (e.g., green), and a third sub-pixel SP3 which provides light of a third color (e.g., blue).

In an embodiment, the first sub-pixel SP1, as a red pixel, may provide light in a wavelength band ranging from about 600 nanometers (nm) to about 750 nm. In such an embodiment, the second sub-pixel SP2, as a green pixel, may provide light in a wavelength band ranging from about 480 nm to about 560 nm, and the third sub-pixel SP3, as a blue pixel, may provide light in a wavelength band ranging from about 370 nm to about 460 nm.

Components for controlling the sub-pixels SP may be disposed in the non-display area NDA on the substrate SUB. In an embodiment, for example, wirings connected to the sub-pixels SP (e.g., gate lines and data lines for driving the sub-pixels SP) may be disposed in the non-display area NDA. Furthermore, a gate driver, a data driver, a voltage generator, a controller, a temperature sensor, and the like may be integrated in the non-display area NDA of the display device 100 to acquire driving signals to be supplied to the sub-pixels SP. However, the disclosure is not limited to the aforementioned example.

The pads PD may be disposed in the non-display area NDA on the substrate SUB. The pads PD may be electrically connected to the sub-pixels SP through the wirings. In an embodiment, for example, the pads PD may be connected to the sub-pixels SP through the data lines.

The pads PD may interface the components in the display area DA and the non-display area NDA with other components of the display device 100. In embodiments, voltages and signals used for the operation of the components included in the display device 100 may be provided from a driver integrated circuit through the pads PD. In an embodiment, for example, the data lines may be electrically connected to the driver integrated circuit through the pads PD. In an embodiment, for example, the power voltages for driving the sub-pixels SP may be received from the driver integrated circuit through the pads PD. In an embodiment, for example, a gate control signal for controlling the gate driver may be transmitted from the driver integrated circuit to the gate driver through the pads PD.

In embodiments, a circuit board may be electrically connected to the pads PD by a conductive adhesive component such as an anisotropic conductive film. Here, the circuit board may be a flexible circuit board or flexible film that is made of flexible material. The driver integrated circuit may be mounted on the circuit board and be electrically connected to the pads PD.

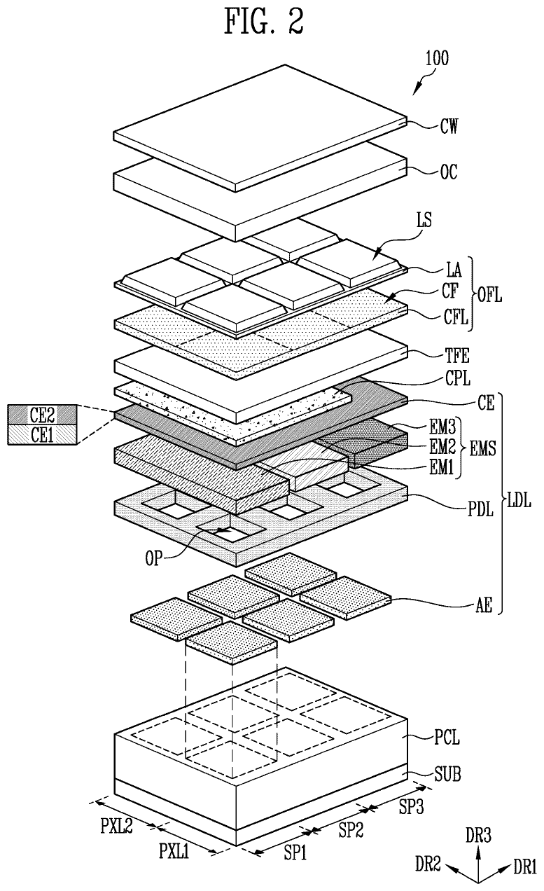

FIG. 2 is a schematic exploded perspective view illustrating the display device 100 in accordance with an embodiment. In FIG. 2, for the sake of clear and concise illustration and description, only a portion of the display device 100 corresponding to two pixels PXL1 and PXL2 among the pixels PXL is schematically illustrated. The remaining portions of the display device 100 corresponding to the other pixels may also be configured in the same manner.

Referring to FIG. 2, each of the first and second pixels PXL1 and PXL2 may include first to third sub-pixels SP1 to SP3. However, the embodiments are not limited to the aforementioned example. In an embodiment, for example, each of the first and second pixels PXL1 and PXL2 may include four sub-pixels, or may include two sub-pixels.

In FIG. 2, it is illustrated an embodiment where the first to third sub-pixels SP1 to SP3 have rectangular shapes and an identical size when viewed in the third direction DR3 crossing the first and second directions DR1 and DR2. However, the embodiments are not limited to the aforementioned example. The first to third sub-pixels SP1 to SP3 may be modified to have various shapes.

In an embodiment, the display device 100 may include a substrate SUB, a pixel circuit layer PCL, a light-emitting-element layer LDL, a capping layer CPL, an encapsulation layer TFE, an optical functional layer OFL, an overcoat layer OC, and a cover window CW.

In embodiments, the substrate SUB may include a silicon wafer substrate formed through a semiconductor process. The substrate SUB may include semiconductor material suitable for forming circuit elements. In an embodiment, for example, the semiconductor material may include silicon, germanium, and/or silicon-germanium. The substrate SUB may be provided or formed from a bulk wafer, an epitaxial layer, a silicon on insulator (SOI) layer, a semiconductor on insulator (SeOI) layer, or the like. In embodiments, the substrate SUB may include a glass substrate. In embodiments, the substrate SUB may include a polyimide (PI) substrate.

The pixel circuit layer PCL may be disposed on the substrate SUB. The substrate SUB and/or the pixel circuit layer PCL may include insulating layers, and conductive patterns located between the insulating layers. The conductive patterns of the pixel circuit layer PCL may function as at least portions of the circuit components, wirings, or the like. The conductive patterns may include various conductive materials. The embodiments are not limited to a specific example. The circuit elements may include respective sub-pixel circuits of the first to third sub-pixels SP1 to SP3. The sub-pixel circuits may each include transistors and one or more capacitors.

The light-emitting-element layer LDL may include anode electrodes AE, a pixel defining layer PDL, an emission structure EMS, and a cathode electrode CE.

The anode electrodes AE may be disposed on the pixel circuit layer PCL. The anode electrodes AE may be electrically connected to circuit elements of the pixel circuit layer PCL.

The pixel defining layer PDL may be placed (or disposed) on the anode electrodes AE. The pixel defining layer PDL may define, therein, openings OP that expose respective portions of the anode electrodes AE. The pixel defining layer PDL may enclose respective edges of the anode electrodes AE, and allows respective portions of the anode electrodes AE to be exposed. The openings OP defined in the pixel defining layer PDL may be understood as respective emission areas corresponding to the first to third sub-pixels SP1 to SP3.

In embodiments, the pixel defining layer PDL may include inorganic material. In such embodiments, the pixel defining layer PDL may include a plurality of inorganic layers stacked on top of one another. In an embodiment, for example, the pixel defining layer PDL may include silicon oxide (SiOx) and silicon nitride (SiNx). However, the material of the pixel defining layer PDL is not limited to the aforementioned examples. In an embodiment, the pixel defining layer PDL may include an organic material.

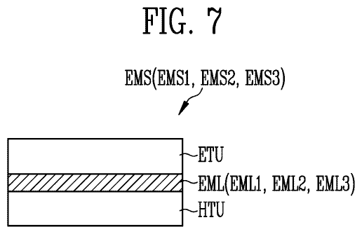

The emission structure EMS may be disposed on the anode electrodes AE that are exposed through the openings OP defined in the pixel defining layer PDL. The emission structure EMS may include an emission layer EML (refer to FIG. 7) configured to generate light, an electron transport component ETU (refer to FIG. 7) configured to transport electrons, and a hole transport component HTU (refer to FIG. 7) configured to transport holes.

In embodiments, the emission structure EMS may be disposed in or charged into the openings OP defined in the pixel defining layer PDL, and may be severed or bent at boundaries between the first to third sub-pixels SP1 to SP3.

The emission structure EMS may include first to third emission structures EMS1 to EMS3 which are spaced apart from each other and respectively form the first to third sub-pixels SP1 to SP3. In an embodiment, for example, the first sub-pixel SP1 may include the first emission structure EMS1. The second sub-pixel SP2 may include the second emission structure EMS2. The third sub-pixel SP3 may include the third emission structure EMS3. The first emission structure EMS1, the second emission structure EMS2, and the third emission structure EMS3 may be formed through different deposition processes, respectively.

The cathode electrode CE may be disposed on the emission structure EMS. The cathode electrode CE may extend across the first to third sub-pixels SP1 to SP3. In such an embodiment, the cathode electrode CE may be provided as a common electrode for the first to third sub-pixels SP1 to SP3.

The cathode electrode CE may be a thin metal layer having a thickness allowing light emitted from the emission structure EMS to pass therethrough.

The cathode electrode CE may have a multilayer structure. In an embodiment, for example, the cathode electrode CE may include a first cathode electrode CE1 and a second cathode electrode CE2.

The first cathode electrode CE1 may be directly adjacent to the emission structure EMS (e.g., an upper surface of the emission structure EMS may be in contact with a lower surface of the first cathode electrode CE1), and may supply a cathode voltage to the emission structure EMS.

In an embodiment, the first cathode electrode CE1 may include silver (Ag), and may further include an additional metal. The additional metal may include at least one selected from magnesium (Mg), aluminum (Al), copper (Cu), calcium (Ca), and barium (Ba).

The second cathode electrode CE2 may be placed on the first cathode electrode CE1. The second cathode electrode CE2 may be located between the first cathode electrode CE1 and the capping layer CPL. A lower surface of the second cathode electrode CE2 may be in contact with an upper surface of the first cathode electrode CE1. An upper surface of the second cathode electrode CE2 may be in contact with a lower surface of the capping layer CPL. The second cathode electrode CE2 may be electrically connected to a wiring (e.g., a low voltage wiring) which applies a cathode voltage to the second cathode electrode CE2.

The second cathode electrode CE2 may include transparent conductive material. In an embodiment, for example, the second cathode electrode CE2 may include transparent conductive oxide (TCO). In an embodiment, for example, the second cathode electrode CE2 may include at least one selected form indium zinc oxide (IZO), indium oxide (IO), tin oxide (TO), indium tin oxide (ITO), indium gallium zinc oxide (IGZO), aluminum zinc oxide (AZO), aluminum tin oxide (ATO), indium tin zinc oxide (ITZO), zinc oxide (ZnO), and tin oxide (SnO₂). In an embodiment, for example, the second cathode electrode CE2 may include IZO. In an embodiment, the second cathode electrode CE2 may be fabricated through a sputtering process. However, the disclosure is not limited to the aforementioned example.

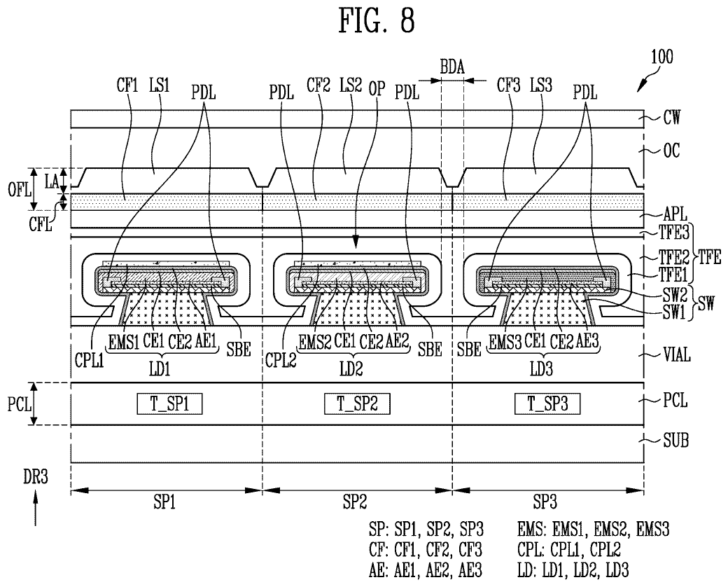

In an embodiment, as the second cathode electrode CE2 is placed on the first cathode electrode CE1, the risk of a cathode connection path being interrupted between the sub-pixels SP may be reduced. For example, in a case where the cathode electrode CE is severed by a sidewall SW (refer to FIGS. 6 and 8), which is provided to sever at least a portion of the emission structure EMS, the cathode connection path may not be thoroughly secured, and risks, such as voltage drop, may occur. In an embodiment, the cathode electrode CE may have a multilayer structure, such that the second cathode electrode CE2 may be placed on the first cathode electrode CE1, thereby reducing the aforementioned risks.

In an embodiment, the second cathode electrode CE2 may include transparent conductive material, such as IZO, thereby having relatively low surface resistance. Accordingly, the characteristics of the light emitting element LD may be improved, thereby reducing power consumption required to drive the pixel PXL. Furthermore, as the second cathode electrode CE2 includes transparent conductive material, such as IZO, loss of light emitted out of the display device 100 may be minimized.

Any one of the anode electrodes AE, a portion of the emission structure EMS that overlap the any one of the anode electrodes AE, or a portion of the cathode electrode CE that overlaps the portion of the emission structure EMS can be understood as constituting one light emitting element LD. In other words, each of the light emitting elements of the first to third sub-pixels SP1 to SP3 may include one anode electrode AE, a portion of the emission structure EMS that overlaps the one anode electrode AE, and a portion of the cathode electrode CE that overlaps the portion of the emission structure EMS. In each of the first to third sub-pixels SP1 to SP3, holes injected from the anode electrode AE and electrons injected from the cathode electrode CE are transported into the emission layer EML of the emission structure EMS, thus forming excitons. When the excitons make a transition from an excited state to a ground state, light can be generated. The luminance of light may be determined based on the amount of current flowing through the emission layer EML. Depending on the configuration of the emission layer EML, the wavelength range of the generated light may be determined.

The capping layer CPL may be placed on the cathode electrode CE (e.g., the second cathode electrode CE2). The capping layer CPL may cover some of the light emitting elements LD. In an embodiment, for example, the capping layer CPL may cover a portion of the second cathode electrode CE2. The capping layer CPL may be a functional layer capable of improving the emission efficiency of the light emitting element LD. Detailed description pertaining to the foregoing will be provided below.

The capping layer CPL may have transmittance and refractive index substantially identical to those of the second cathode electrode CE located under the capping layer CPL. In an embodiment, for example, the capping layer CPL may have a first transmittance and a first refractive index with respect to light in a visible light range (e.g., light with a wavelength ranging from about 380 nm to about 770 nm), and the second cathode electrode CE2 may have a second transmittance and a second refractive index with respect to light in a visible light range. The first transmittance may be in a range from 0.9 to 1.1 times the second transmittance. The first refractive index may be in a range from 0.9 to 1.1 times the second refractive index.

The encapsulation layer TFE may be placed on the capping layer CPL. The encapsulation layer TFE may cover the capping layer CPL, the light-emitting-element layer LDL, and the pixel circuit layer PCL. The encapsulation layer TFE may prevent oxygen, moisture, and/or the like from penetrating into the light-emitting-element layer LDL. In embodiments, the encapsulation layer TFE may include a structure formed by alternately stacking one or more inorganic layers and one or more organic layers. In an embodiment, for example, the inorganic layer may include, for example, silicon nitride, silicon oxide, or silicon oxynitride. In an embodiment, for example, the organic layer may include organic insulating material, such as acrylic resin, epoxy resin, phenol resin, polyamide resin, polyimide resin, unsaturated polyester resin, polyphenylenether resin, polyphenylenesulfide resin, or benzocyclobutene (BCB). However, the materials of the organic layer and the inorganic layer of the encapsulation layer TFE are not limited to the aforementioned examples.

The optical functional layer OFL may be placed on the encapsulation layer TFE. The optical functional layer OFL may include a color filter layer CFL and a lens array LA.

The color filter layer CFL may be located between the encapsulation layer TFE and the lens array LA. The color filter layer CFL may filter light emitted from the emission structure EMS and selectively output light in a wavelength range or color corresponding to each sub-pixel. The color filter layer CFL may include color filters CF which respectively correspond to the first to third sub-pixels SP1 to SP3. Each of the color filters CF may transmit light within a wavelength range corresponding to the related sub-pixel. In an embodiment, for example, the color filter that corresponds to the first sub-pixel SP1 may transmit light in a red color, the color filter that corresponds to the second sub-pixel SP2 may transmit light in a green color, and the color filter that corresponds to the third sub-pixel SP3 may transmit light in a blue color. Depending on the light emitted from the emission structure EMS of each sub-pixel, at least some of the color filters CF may be omitted.

The lens array LA may be placed on the color filter layer CFL. The lens array LA may include lenses LS that respectively correspond to the first to third sub-pixels SP1 to SP3. Each of the lenses LS may output and direct light emitted from the emission structure EMS along an intended path, thus enhancing the light output efficiency. The lens array LA may have a relatively high refractive index. For example, the lens array LA may have a higher refractive index than the overcoat layer OC. In embodiments, the lenses LS may include organic material. In embodiments, the lenses LS may include acrylic material. However, the material of the lenses LS is not limited to the foregoing example.

The overcoat layer OC may be placed on the lens array LA. The overcoat layer OC may cover the optical functional layer OFL, the encapsulation layer TFE, the emission structure EMS, and/or the pixel circuit layer PCL. The overcoat layer OC may include various materials suitable for protecting underlying layers from foreign substances, such as dust, moisture, or the like. In an embodiment, for example, the overcoat layer OC may include at least one of an inorganic insulating layer or an organic insulating layer. In an embodiment, for example, the overcoat layer OC may include epoxy, but the embodiments are not limited thereto. The overcoat layer OC may have a lower refractive index than the lens array LA.

The cover window CW may be placed on the overcoat layer OC. The cover window CW may protect underlying layers. The cover window CW may have a higher refractive index than the overcoat layer OC. The cover window CW may include glass, but the embodiments are not limited thereto. In an embodiment, for example, the cover window CW may be an encapsulation glass layer configured to protect components located thereunder. In other embodiments, the cover window CW may be omitted.

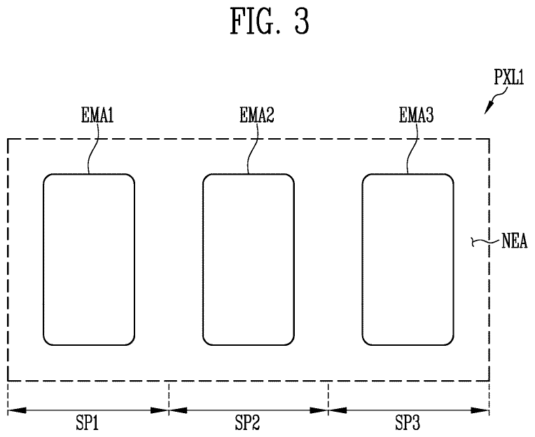

FIG. 3 is a plan view illustrating an embodiment of one of the pixels of FIG. 2. In FIG. 3, for the sake of clear and concise illustration and description, only the first pixel PXL1 of FIG. 2 is schematically depicted as a representative example of the first pixel PXL1 and the second pixel PXL2. The other pixels may be configured in the same manner as the first pixel PXL1.

Referring to FIGS. 2 and 3, in an embodiment, the first pixel PXL1 may include a first sub-pixel SP1, a second sub-pixel SP2, and a third sub-pixel SP3 which are arranged in the first direction DR1.

The first sub-pixel SP1 may include a first emission area EMA1 and a non-emission area NEA formed around the first emission area EMA1. The second sub-pixel SP2 may include a second emission area EMA2 and a non-emission area NEA formed around the second emission area EMA2. The third sub-pixel SP3 may include a third emission area EMA3 and a non-emission area NEA formed around the third emission area EMA3.

The first emission area EMA1 may be an area where light is emitted from a portion of the emission structure EMS (e.g., from the first emission structure EMS1) that corresponds to the first sub-pixel SPX1. The second emission area EMA2 may be an area where light is emitted from a portion of the emission structure EMS (e.g., from the second emission structure EMS2) that corresponds to the second sub-pixel SP2. The third emission area EMA3 may be an area where light is emitted from a portion of the emission structure EMS (e.g., from the third emission structure EMS3) that corresponds to the third sub-pixel SP3. As described with reference to FIG. 2, the emission areas may be understood as the respective openings OP of the pixel defining layer PDL that correspond to the first sub-pixel SP1, the second sub-pixel SP2, and the third sub-pixel SP3.

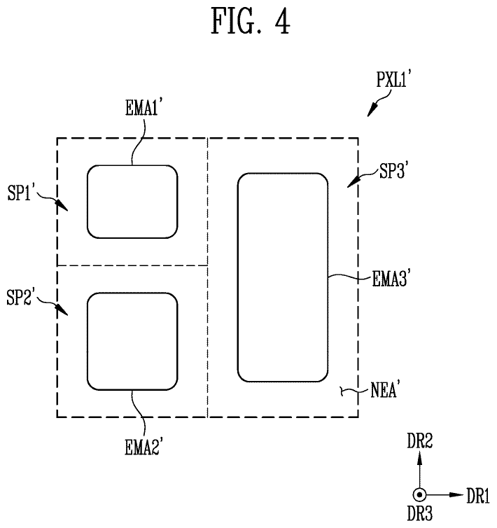

FIG. 4 is a plan view illustrating another embodiment of one of the pixels of FIG. 2.

Referring to FIG. 4, in another embodiment, a first pixel PXL1′ may include first to third sub-pixels SP1′ to SP3′.

The first sub-pixel SP1′ may include a first emission area EMA1′ and a non-emission area NEA′ formed around the first emission area EMA1′. The second sub-pixel SP2′ may include a second emission area EMA2′ and a non-emission area NEA′ formed around the second emission area EMA2′. The third sub-pixel SP3′ may include a third emission area EMA3′ and a non-emission area NEA′ formed around the third emission area EMA3′.

The first sub-pixel SP1′ and the second sub-pixel SP2′ may be arranged in the second direction DR2. The third sub-pixel SP3′ may be located in the first direction DR1 with respect to each of the first and second sub-pixels SP1′ and SP2′.

The second sub-pixel SP2′ may have a larger surface area than the first sub-pixel SP1′. The third sub-pixel SP3′ may have a larger surface area than the second sub-pixel SP2′. Therefore, the second emission area EMA2′ may have a larger surface area than the first emission area EMA1′. The third emission area EMA3′ may have a larger surface area than the second emission area EMA2′. However, the embodiments are not limited to the aforementioned example. In an embodiment, for example, the first and second sub-pixels SP1′ and SP2′ may have substantially a same surface area or planar area. The third sub-pixel SP3′ may have a larger surface area than each of the first and second sub-pixels SP1′ and SP2′. In such an embodiment, the surface areas of the first to third sub-pixels SP1′ to SP3′ may be changed in various ways depending on the embodiments.

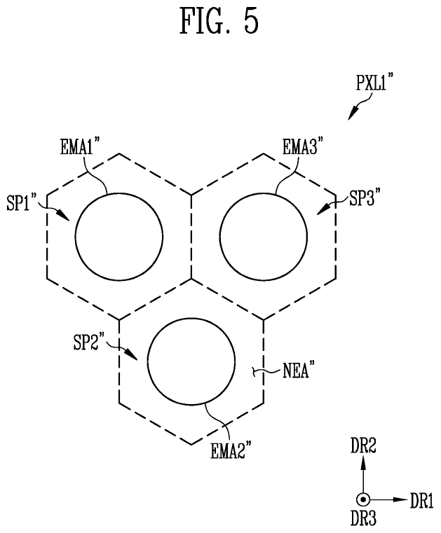

FIG. 5 is a plan view illustrating another embodiment of one of the pixels of FIG. 2.

Referring to FIG. 5, in an embodiment, a first sub-pixel SP1” may include a first emission area EMA1” and a non-emission area NEA” formed around the first emission area EMA1”. A second sub-pixel SP2” may include a second emission area EMA2” and a non-emission area NEA” formed around the second emission area EMA2”. A third sub-pixel SP3” may include a third emission area EMA3” and a non-emission area NEA” formed around the third emission area EMA3”.

Each of the first to third sub-pixels SP1” to SP3” may have a polygonal shape in the third direction DR3. In an embodiment, for example, the shapes of the first to third sub-pixels SP1” to SP3” may be hexagonal, as illustrated in FIG. 2.

Each of the first to third emission areas EMA1” to EMA3” may have a circular shape in the third direction DR3. However, the embodiments are not limited to the aforementioned example. In an embodiment, for example, each of the first to third emission areas EMA1” to EMA3” may have a polygonal shape.

The first and third sub-pixels SP1” and SP3” may be arranged in the first direction DR1. The second sub-pixel SP2” may be positioned in a direction (or a diagonal direction) inclined at an acute angle relative to the second direction DR2 with respect to the first sub-pixel SP1”.

The arrangements of the sub-pixels illustrated in FIGS. 3 to 5 are illustrative, and the embodiments are not limited thereto. Each pixel PXL may include two or more sub-pixels SP. The sub-pixels SP may be arranged in various ways. Each of the sub-pixels SP may have various shapes, and each of the emission areas EMA1, EMA2, and EMA3 of the sub-pixels SP may have various shapes.

FIG. 6 is a schematic sectional view illustrating the display device 100 in accordance with an embodiment. FIG. 6 schematically illustrates the first to third sub-pixels SP1 to SP3. FIG. 7 is a schematic sectional view illustrating the emission structure EMS in accordance with an embodiment.

Referring to FIG. 6, in an embodiment, the substrate SUB and the pixel circuit layer PCL placed on the substrate SUB may be provided.

The pixel circuit layer PCL may be placed on the substrate SUB. The substrate SUB and the pixel circuit layer PCL may include respective circuit elements of the first to third sub-pixels SP1 to SP3. In an embodiment, for example, the substrate SUB and the pixel circuit layer PCL may include a transistor T_SP1 of the first sub-pixel SP1, a transistor T_SP2 of the second sub-pixel SP2, and a transistor T_SP3 of the third sub-pixel SP3.

A via layer VIAL may be placed on the pixel circuit layer PCL. The via layer VIAL may cover the pixel circuit layer PCL, and have an overall flat (upper) surface. The via layer VIAL may planarize stepped portions therebelow on the pixel circuit layer PCL. The via layer VIAL may include at least one selected from silicon oxide (SiOx), silicon nitride (SiNx), or silicon carbon nitride (SiCN), but embodiments are not limited thereto.

Although not illustrated in FIG. 6, in an embodiment, a planarization layer and first to third reflective electrodes may further be disposed between the via layer VIAL and the light-emitting-element layer LDL. In an embodiment, the first to third sub-pixels SP1 to SP3 may respectively include first to third reflective electrodes. The first to third reflective electrodes may be respectively arranged in first to third sub-pixel areas in which the first to third sub-pixels SP1 to SP3 are respectively defined (or located). The first to third reflective electrodes may be placed on the via layer VIAL, and may function as full mirrors which reflect light emitted from the emission structure EMS toward a display surface (or the cover window CW). The planarization layer may be placed on the first to third reflective electrodes. The planarization layer may cover overall surfaces of the first to third reflective electrodes and the via layer VIAL, and may form a flat surface.

The light-emitting-element layer LDL may be placed on the via layer VIAL. The light-emitting-element layer LDL may include the first to third anode electrodes AE1 to AE3, the pixel defining layer PDL, the emission structure EMS, and the cathode electrode CE.

The first to third anode electrodes AE1 to AE3, which respectively overlap the first to third first to third sub-pixels SP1 to SP3, may be arranged on the via layer VIAL. The first to third sub-pixels SP1 to SP3 may respectively include the first to third anode electrodes AE1 to AE3.

In embodiments, the first to third anode electrodes AE1 to AE3 may include at least one selected from transparent conductive materials, such as indium tin oxide (ITO), indium zinc oxide (IZO), zinc oxide (ZnOx), indium gallium zinc oxide (IGZO), and indium tin zinc oxide (ITZO). However, the material of the first to third anode electrodes AE1 to AE3 is not limited to the aforementioned example. In an embodiment, for example, the first to third anode electrodes AE1 to AE3 may each include titanium nitride.

The pixel defining layer PDL may be placed on respective portions of the first to third anode electrodes AE1 to AE3. In an embodiment, for example, the pixel defining layer PDL may enclose respective edges of the first to third anode electrodes AE1 to AE3 while allowing at least respective portions of the first to third anode electrodes AE1 to AE3 to be exposed.

In an embodiment, the display device 100 may further include sidewalls SW placed on the pixel defining layer PDL. In an embodiment, the pixel defining layer PDL may be located under the sidewalls SW. The pixel defining layer PDL may overlap the sidewalls SW. The sidewalls SW may be located in a boundary area BDA between the sub-pixels SP. The sidewalls SW may be located between adjacent emission structures EMS. In an embodiment, for example, the sidewalls SW may be located in respective areas between the first emission structure EMS1, the second emission structure EMS2, and the third emission structure EMS3.

Each of the sidewalls SW may include a first sidewall SW1 and a second sidewall SW2 placed on the first sidewall SW1. The first sidewall SW1 may form a base on which the second sidewall SW2 is placed. In an embodiment, a lower surface of the first sidewall SW1 may contact an upper surface of the pixel defining layer PDL. The second sidewall SW2 may have a width larger than that of the first sidewall SW1, thereby forming a tip which protrudes in a planar direction in which the substrate SUB is positioned. In an embodiment, for example, each of the sidewalls SW may have a “T” shaped structure or an undercut structure with the second sidewall SW2 protruding further than the first sidewall SW1.

Each of the first sidewall SW1 and the second sidewall SW2 may include conductive material. At least a portion of the sidewall SW may be electrically connected to the cathode electrode CE, thus forming an electrical cathode connection path. In an embodiment, for example, the first sidewall SW1 may include aluminum, and the second sidewall SW2 may include titanium. The cathode electrode CE may be electrically connected to a side surface of the first sidewall SW1. The material of each of the first sidewall SW1 and the second sidewall SW2 is not limited to aluminum or titanium, and may include various conductive materials. Although not illustrated in the drawings, the sidewalls SW may be electrically connected to other power wirings by contactors which pass through the pixel defining layer PDL or the like.

The sidewalls SW may result in creation of discontinuities in the emission structures EMS in the boundary area BDA. In an embodiment, for example, the emission structures EMS may be severed or bent in the boundary area BDA defined by the sidewalls SW.

The emission structures EMS may be disposed on the anode electrodes AE that are exposed through the openings OP defined in the pixel defining layer PDL. In an embodiment, for example, the first emission structure EMS1 may be placed on the anode electrode AE1 of the first sub-pixels SP1. The second emission structure EMS2 may be placed on the anode electrode AE2 of the second sub-pixels SP2. The third emission structure EMS3 may be placed on the anode electrode AE3 of the third sub-pixels SP3.

Referring to FIG. 7, the emission structure EMS may include a hole transport component HTU, an emission layer EML, and an electron transport component ETU. Each of the layers that form the emission structure EMS may include an organic material and, in an embodiment, may further include an inorganic material, such as a metal-containing compound or quantum dot.

The hole transport component HTU may include a multilayer structure including a plurality of layers which respectively include different materials. In an embodiment, for example, the hole transport component HTU may include a hole injection layer and a hole transport layer and, in an embodiment, may further include an auxiliary emission layer, an electron blocking layer, or the like.

The emission layer EML may include a material capable of emitting light of one color. The emission layer EML may include a host and a dopant. The host of the emission layer EML may be an emission material capable of capturing carriers (electrons and holes) for light generation, thus inducing efficient exciton generation. The dopant may include a phosphorescent dopant or a fluorescent dopant. In an embodiment, examples of the dopant are not specifically limited. In an embodiment, the dopant may include an organic material, and may include a metal complex or the like.

The emission structure EMS (or the emission layer EML) in accordance with the disclosure may include an organic emission material, and the display device 100 may be a display device including an organic light emitting diode (OLED).

The electron transport component ETU may include a multilayer structure with a plurality of layers which respectively have different materials. The electron transport component ETU may include an electron injection layer and an electron transport layer and, in an embodiment, may further include an electron buffer layer, a hole blocking layer, or the like.

The first to third emission structures EMS1 to EMS3 may include at least respective portions of the hole transport component HTU and/or the electron transport component ETU as a common layer, and may respectively include first to third emission layers EML1 to EML3 different from each other.

The cathode electrode CE may be disposed on the emission structure EMS. The cathode electrode CE may be provided in common in the first to third sub-pixels SP1 to SP3. The cathode electrode CE may function as a half mirror, partially transmitting and partially reflecting light emitted from the emission structure EMS.

In an embodiment, as described above, the cathode electrode CE may include the first cathode electrode CE1 and the second cathode electrode CE2. The second cathode electrode CE2 may cover at least the boundary area BDA, enable a cathode connection path to be precisely formed, and reduce risks, such as voltage drop.

A first surface (e.g., a lower surface) of the first cathode electrode CE1 may contact each of the first to third emission structures EMS1, EMS2, and EMS3. A second surface (e.g., an upper surface) of the first cathode electrode CE1 may contact the second cathode electrode CE2. A first surface (e.g., a lower surface) of the second cathode electrode CE2 may contact the first cathode electrode CE1. A second surface (e.g., an upper surface) of the second cathode electrode CE2 may contact the capping layer CPL.

The first anode electrode AE1, the first emission structure EMS1 that overlaps the first anode electrode AE1, and the portion of the cathode electrode CE that overlaps the first anode electrode AE1 may form a first light emitting element LD1. The second anode electrode AE2, the second emission structure EMS2 that overlaps the second anode electrode AE2, and the portion of the cathode electrode CE that overlaps the second anode electrode AE2 may form a second light emitting element LD2. The third anode electrode AE3, the third emission structure EMS3 that overlaps the third anode electrode AE3, and the portion of the cathode electrode CE that overlaps the third anode electrode AE3 may form a third light emitting element LD3.

In an embodiment, the capping layer CPL may be placed on the cathode electrode CE. The capping layer CPL may include an organic material, and may have a relatively high refractive index.

The capping layer CPL may be placed on the second cathode electrode CE2. The capping layer CPL may contact the second cathode electrode CE2. The capping layer CPL may not overlap at least one selected from the first to third sub-pixels SP1 to SP3 in a plan view (or in the third direction DR3). In an embodiment, for example, the capping layer CPL may not overlap at least one selected from the first emission structure EMS1, the second emission structure EMS2, or the third emission structure EMS3 in a plan view. In an embodiment, the capping layer CPL may not overlap one of the first emission structure EMS1, the second emission structure EMS2, or the third emission structure EMS3 in a plan view, and may overlap remaining two in a plan view. In an embodiment, for example, as illustrated in FIG. 6, the capping layer CPL may include a first capping layer CPL1 and a second capping layer CPL2. The first capping layer CPL1 may overlap the first emission structure EMS1 in a plan view. The second capping layer CPL2 may overlap the second emission structure EMS2 in a plan view. The capping layer CPL may not overlap the third emission structure EMS3 in a plan view.

The plane defined in the disclosure may extend in the first direction DR1 and the second direction DR2, and may be defined based on the plane on which the substrate SUB is disposed.

Hereinafter, the first capping layer CPL1 may be defined as a portion of the capping layer CPL which overlaps the first emission structure EMS1 in a plan view and does not overlap the second emission structure EMS2 and the third emission structure EMS3 in a plan view. The second capping layer CPL2 may be defined as a portion of the capping layer CPL which overlaps the second emission structure EMS2 in a plan view and does not overlap the first emission structure EMS1 and the third emission structure EMS3 in a plan view. A third capping layer may be defined as a portion of the capping layer CPL which overlaps the third emission structure EMS3 in a plan view and does not overlap the first emission structure EMS1 and the second emission structure EMS2 in a plan view. The first capping layer CPL1, the second capping layer CPL2, and the third capping layer may be formed through different processes.

In FIG. 6, an embodiment where the capping layer CPL does not overlap only the third emission structure EMS3 among the first emission structure EMS1, the second emission structure EMS2, and the third emission structure EMS3 is illustrated. The disclosure is not limited to the aforementioned example. In a plan view, the capping layer CPL may not overlap one of the first emission structure EMS1, the second emission structure EMS2, and the third emission structure EMS3, while overlapping the other two of the first emission structure EMS1, the second emission structure EMS2 and the third emission structure EMS3. In an embodiment, for example, the capping layer CPL may overlap the second emission structure EMS2 and the third emission structure EMS3 in a plan view, and may not overlap the first emission structure EMS1 in a plan view. In such an embodiment, the capping layer CPL may include the second capping layer CPL2 and the third capping layer. In an embodiment, for example, the capping layer CPL may overlap the first emission structure EMS1 and the third emission structure EMS3 in a plan view, and may not overlap the second emission structure EMS2 in a plan view. In such an embodiment, the capping layer CPL may include the first capping layer CPL1 and the third capping layer. In other words, in an embodiment, the capping layer CPL may include only two of the first capping layer CPL1, the second capping layer CPL2, and the third capping layer. In such an embodiment, the capping layer CPL may not overlap only one of the first emission structure EMS1, the second emission structure EMS2, and the third emission structure EMS3.

However, the disclosure is not limited to the aforementioned example. In an embodiment, the capping layer CPL may not overlap two of the first emission structure EMS1, the second emission structure EMS2, and the third emission structure EMS3 in a plan view, and may overlap a remaining one of the first emission structure EMS1, the second emission structure EMS2, and the third emission structure EMS3 in a plan view. In an embodiment, for example, the capping layer CPL may not overlap the second emission structure EMS2 and the third emission structure EMS3 in a plan view, and may overlap the first emission structure EMS1 in a plan view. In an embodiment, for example, the capping layer CPL may not overlap the first emission structure EMS1 and the third emission structure EMS3 in a plan view, and may overlap the second emission structure EMS2 in a plan view. In an embodiment, for example, the capping layer CPL may not overlap the first emission structure EMS1 and the second emission structure EMS2 in a plan view, and may overlap the third emission structure EMS3 in a plan view. In other words, in an embodiment, the capping layer CPL may include only one of the first capping layer CPL1, the second capping layer CPL2, and the third capping layer. In such an embodiment, the capping layer CPL may not overlap only two of the first emission structure EMS1, the second emission structure EMS2, and the third emission structure EMS3.

In an embodiment, the capping layer CPL may overlap one or two of the first emission structure EMS1, the second emission structure EMS2, and the third emission structure EMS3 in a plan view, and may not overlap remaining one or two of the first emission structure EMS1, the second emission structure EMS2, and the third emission structure EMS3 in a plan view. Accordingly, the efficiency of light emitted from the first to third sub-pixels SP1 to SP3 may be enhanced.

In an embodiment, at least a portion of each material formed in a same process as the first to third emission structures EMS1 to EMS3, at least a portion of a material formed in a same process as the cathode electrode CE, and at least a portion of a material formed in a same process as the capping layer CPL may each be placed on the corresponding second sidewall SW2.

The encapsulation layer TFE may be placed on the capping layer CPL. The encapsulation layer TFE may contact the capping layer CPL. The encapsulation layer TFE may prevent oxygen, moisture, and/or the like from penetrating into the light-emitting-element layer LDL.

In an embodiment, the encapsulation layer TFE may include first to third encapsulation layers TFE1 to TFE3. In an embodiment, the first encapsulation layer TFE1 may include an inorganic layer, the second encapsulation layer TFE2 may include an organic layer, and the third encapsulation layer TFE3 may include an inorganic layer. The first encapsulation layer TFE1 may passivate the light emitting elements LD, the capping layer CPL, and the sidewalls SW. The second and third encapsulation layers TFE2 and TFE3 may be sequentially stacked on the first encapsulation layer TFE1. In an embodiment, the encapsulation layer TFE may be formed as a single layer.

The optical functional layer OFL may be placed on the encapsulation layer TFE. In embodiments, the optical functional layer OFL may be attached to the encapsulation layer TFE through an adhesive layer APL. In an embodiment, for example, the optical functional layer OFL may be fabricated through a separate process and attached to the encapsulation layer TFE by the adhesive layer APL. The adhesive layer APL may further perform a function of protecting underlying layers including the encapsulation layer TFE.

The optical functional layer OFL may include a color filter layer CFL and a lens array LA. The color filter layer CFL may include first to third color filters CF1 to CF3 which respectively correspond to the first to third sub-pixels SP1 to SP3. The first to third color filters CF1 to CF3 may transmit light in different wavelength ranges. In an embodiment, for example, the first to third color filters CF1 to CF3 may respectively transmit red light, green light, and blue light.

In embodiments, the first to third color filters CF1 to CF3 may partially overlap each other in the boundary area BDA. In other embodiments, the first to third color filters CF1 to CF3 may be spaced apart from each other, and a black matrix may be provided between the first to third color filters CF1 to CF3.

The lens array LA may be placed on the color filter layer CFL. The lens array LA may include first to third lenses LS1 to LS3 which respectively correspond to the first to third sub-pixels SP1 to SP3. The first to third lenses LS1 to LS3 may respectively direct light emitted from the first to third light emitting elements LD1 to LD3 in desired paths, thus enhancing the light output efficiency.

FIG. 8 is a schematic sectional view illustrating the display device 100 in accordance with an embodiment. The embodiment illustrated in FIG. 8 is substantially the same as the embodiment illustrated in FIG. 6 except that pixel defining layers PDL and anode electrodes AE are placed on sidewalls SW (e.g., second sidewalls SW2). Any repetitive detailed descriptions of the same or like elements as those described above will be simplified or omitted.

In an embodiment, as shown in FIG. 8, the sidewalls SW may be arranged to respectively overlap the first to third sub-pixels SP1 to SP3. In an embodiment, for example, the sidewalls SW may be respectively located in the first to third sub-pixel areas in which the first to third sub-pixels SP1 to SP3 are respectively defined. In an embodiment, for example, the sidewalls SW may not overlap the boundary area BDA between the first to third sub-pixels SP1 to SP3, in a plan view. In an embodiment, for example, with reference to FIG. 3, the sidewalls SW may overlap the first to third emission areas EMA1 to EMA3 in a plan view.

In an embodiment, each of the sidewalls SW may include insulating material. In an embodiment, for example, the sidewall SW (specifically, each of the first sidewall SW1 and the second sidewall SW2) may include at least one of an inorganic insulating material or an organic insulating material. The inorganic insulating material may include at least one selected from silicon nitride, silicon oxide, or silicon oxynitride. The organic insulating material may include at least one selected from acrylic resin, epoxy resin, phenol resin, polyamide resin, polyimide rein, unsaturated polyester resin, polyphenyleneether resin, polyphenylenesulfide resin, or benzocyclobutene (BCB).

First to third anode electrodes AE1 to AE3 may be respectively placed on the second sidewalls SW2. In an embodiment, for example, the first to third anode electrodes AE1 to AE3 may be respectively placed on the second sidewalls SW2 which respectively overlap the first to third sub-pixels SP1 to SP3. A distance between each of the first to third anode electrodes AE1 to AE3 and the via layer VIAL may be greater than a distance between each of the second sidewalls SW2 and the via layer VIAL.

The first to third anode electrodes AE1 to AE3 may respectively overlap the second sidewalls SW2 in a plan view. In a plan view or when viewed in the third direction DR3, a surface area of each of the first to third anode electrodes AE1 to AE3 may be less than that of each of the second sidewalls SW2. Each of the first to third anode electrodes AE1 to AE3 may have an end which is not aligned with that of the corresponding second sidewall SW2 in a plan view.

In an embodiment, the display device 100 may further include sub-electrodes SBE which are located between the second sidewalls SW2 and the first to third anode electrodes AE1 to AE3. The sub-electrodes SBE may overlap the first to third anode electrodes AE1 to AE3 in a plan view, and may contact the first to third anode electrodes AE1 to AE3. The sub-electrodes SBE may contact the second sidewalls SW2.

The sub-electrodes SBE may include a conductive material and, although not illustrated in the drawings, the sub-electrodes SBE may be electrically connected to other power wirings by passing through the sidewalls SW or the like.

In an embodiment, an insulating material may be further provided between the sub-electrodes SBE and the second sidewalls SW2. In such an embodiment, each of the sidewalls may include a conductive material instead of an insulating material, and may be electrically connected to the cathode electrode CE.

The pixel defining layers PDL may be respectively placed on the first to third anode electrodes AE1 to AE3. In an embodiment, each of the pixel defining layers PDL may be placed on the corresponding sidewall SW (e.g., the corresponding second sidewall SW2). A distance between the pixel defining PDL and the via layer VIAL may be greater than a distance between the second sidewall SW2 and the via layer VIAL.

Each of the first to third emission structures EMS1 to EMS3 may have a surface area greater than that of each of the second sidewalls SW2 in a plan view. Each of the first to third emission structures EMS1 to EMS3 may enclose the corresponding pixel defining layer PDL and the corresponding second sidewall SW2.

In an embodiment, the first to third emission structures EMS1 to EMS3 may respectively form or define first to third light emitting elements LD1 to LD3 on the corresponding sidewalls SW. Each of the first to third emission structures EMS1 to EMS3 may be placed on the corresponding sidewall SW, thereby effectively preventing shadow effects during a process of depositing the first to third emission structures EMS1 to EMS3, and enhancing the resolution of the display device 100.

In an embodiment according to FIG. 8, as described above with reference to FIG. 6, the capping layer CPL may overlap one or two of the first emission structure EMS1, the second emission structure EMS2, and the third emission structure EMS3 in a plan view, and may not overlap remaining one or two of the first emission structure EMS1, the second emission structure EMS2, and the third emission structure EMS3 in a plan view. Accordingly, the efficiency of light emitted from the first to third sub-pixels SP1 to SP3 may be enhanced.

The first cathode electrode CE1 may be placed on each of the first to third emission structures EMS1 to EMS3. The second cathode electrode CE2 may be placed on the first cathode electrode CE1, and may extend to enclose a corresponding one of the first to third emission structures EMS1 to EMS3 and the corresponding sidewall SW (e.g., the corresponding second sidewall SW2). In an embodiment, for example, the second cathode electrode CE2 may contact a side surface of the corresponding one of the first to third emission structures EMS1 to EMS3, and may extend to enclose the corresponding second sidewall SW2 and contact a side surface of the corresponding first sidewall SW1.

Although not illustrated in the drawing, the second cathode electrode CE2 may extend to contact the side surface of the first sidewall SW1, and may be electrically connected to a wiring that is provided on the via layer VIAL to apply a cathode voltage to the second cathode electrode CE2.

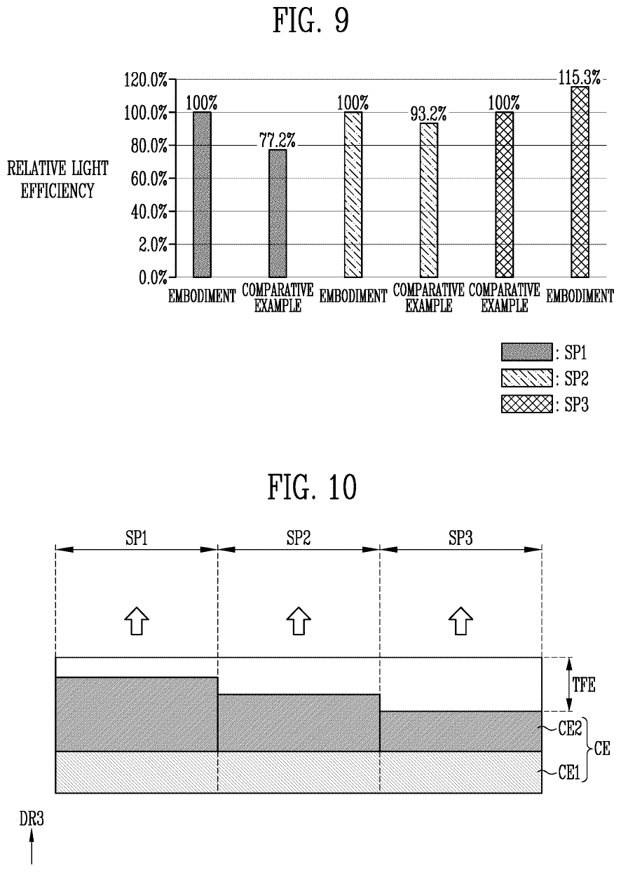

FIG. 9 is a graph illustrating experimental results of relative light efficiency for respective sub-pixels in accordance with an embodiment. FIG. 9 illustrates the relative light efficiency for the respective sub-pixels, measured in a comparative example and an embodiment.

In FIG. 9, with regard to each of the comparative example and the embodiment, a light efficiency value for the red color corresponding to the first sub-pixel SP1, a light efficiency value for the green color corresponding to the second sub-pixel SP2, and a light efficiency value for the blue color corresponding to the third sub-pixel SP3 are shown in the graph. The relationships between hatchings of respective graphs and the sub-pixels SP corresponding to different colors are indicated in the lower right corner.

The comparative example illustrates the case where the capping layer overlaps all of the first to third sub-pixels SP1 to SP3, that is, all of the first capping layer CPL1, the second capping layer CPL2, and the third capping layer are included. The embodiment illustrated in FIG. 9 may correspond to the embodiment illustrated in FIG. 8, which includes the first capping layer CPL1 and the second capping layer CPL2 but does not include the third capping layer. Except for the foregoing difference, the comparative example and the embodiment in FIG. 9 may have identical material and structure. For example, the embodiment and the comparative example may include a sidewall SW, an anode electrode AE, an emission structure EMS, and a cathode electrode CE, each of which includes an identical material.

In the comparative example, a light efficiency Cd/A of light applied from each of the firs to third sub-pixels SP1 to SP3 is measured. A light efficiency measured in the embodiment is calculated as a relative value and indicated in FIG. 9.

Referring to FIG. 9, it can be shown that the embodiment can provide improved light efficiency in the visible light range for each of the sub-pixels, compared to the comparative example. Accordingly, it can be understood that the embodiment that includes the first capping layer CPL1 and the second capping layer CPL2 but does not include the third capping layer can provide a display device 100 that is improved in terms of the light efficiency compared to the case that includes all of the first capping layer CPL1, the second capping layer CPL2, and the third capping layer.

Experimentally, since the capping layer CPL may include organic material, the capping layer CPL may have a relatively low refractive index in a long-wavelength range (e.g., a wavelength range of about 500 nm or greater) compared to the range excluding the long-wavelength range. Furthermore, since the first emission structure EMS1, the second emission structure EMS2, and the third emission structure EMS3 may include different materials, respectively, the first to third sub-pixels SP1 to SP3 may differ in light efficiency.

In FIG. 9, the experimental results of the embodiment that does not include the third capping layer among the first capping layer CPL1, the second capping layer CPL2, and the third capping layer are illustrated. However, depending on the material and stacking structure of the emission structures EMS, the arrangement of the capping layer CPL with improved light efficiency may be changed. The inventor has checked that if the capping layer CPL does not overlap some of the first to third sub-pixels SP1 to SP3, the light efficiency of the light emitting elements LD across the first to third sub-pixels SP1 to SP3 exhibits relatively high values.

In the display device 100 in accordance with an embodiment of the disclosure, the capping layer CPL may be provided not to overlap some of the first to third sub-pixels SP1 to SP3, thereby enhancing the light efficiency of the light emitting elements LD. Accordingly, the lifespan of the display device 100 may be increased.

FIG. 10 is a schematic sectional view illustrating the cathode electrode CE and the encapsulation layer TFE in accordance with an embodiment. The structure of the display device 100 in according with an embodiment of FIG. 10, may be to the same as that of the embodiments illustrated in FIGS. 6 and 8 except for the structures of the capping layer CPL and the cathode electrode CE. The display device 100 in accordance with an embodiment of FIG. 10 may not include the capping layer CPL. Any repetitive detailed descriptions of the same or like elements as those described above will be simplified or omitted.

Referring to FIG. 10, the display device 100 in accordance with an embodiment may not include the capping layer CPL, and the cathode electrode CE (e.g., the second cathode electrode CE2) may contact the encapsulation layer TFE. The encapsulation layer TFE may be directly disposed on the cathode electrode CE (e.g., the second cathode electrode CE2).

The second cathode electrode CE2 may have different thicknesses in the first to third sub-pixels SP1 to SP3. In an embodiment, for example, the second cathode electrode CE2 may have different thicknesses, respectively, in an area where the first emission structure EMS1 is located, an area where the second emission structure EMS2 is located, and an area where the third emission structure EMS3 is located. That is, portions of the second cathode electrode CE2 overlapping the first emission structure EMS1, the second emission structure EMS2 is located, and the third emission structure EMS3, respectively, may have different thicknesses from each other.

To enhance the light efficiency of the light emitting elements LD in the first to third sub-pixels SP1 to SP3, the thickness of the second cathode electrode CE2 may be adjusted. As the second cathode electrode CE2 has different thicknesses in the first to third sub-pixels SP1 to SP3, the light efficiency of the light emitting elements LD in the first to third sub-pixels SP1 to SP3 may be enhanced.

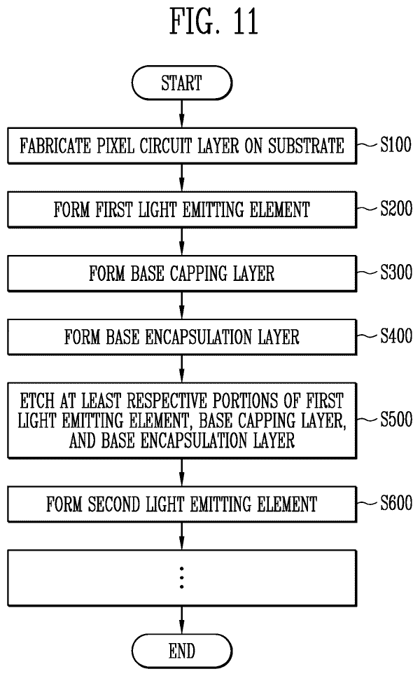

Hereinafter, a method of fabricating the display device 100 in accordance with an embodiment will be described with reference to FIG. 11 and the preceding drawings. Any repetitive detailed descriptions of the same or like elements as those above will be simplified or omitted.

FIG. 11 is a flowchart illustrating a method of fabricating the display device 100 in accordance with an embodiment. The method of fabricating the display device 100 may vary or be variously modified depending on the arrangement relationship of the capping layer CPL. However, the following description of the method of fabricating the display device 100 is based on an embodiment in which the capping layer CPL of the display device 100 overlaps the first sub-pixel SP1 and the second sub-pixel SP2 but does not overlap the third sub-pixel SP3. Furthermore, hereinafter, the first to third emission structures EMS1 to EMS3 will be described as being sequentially formed. However, the disclosure is not limited to thereto, and the third emission structure EMS3 may be formed before the first emission structure EMS1 is formed.

The method of fabricating the display device 100 in accordance with an embodiment may include process S100 of fabricating the pixel circuit layer PCL on the substrate SUB, process S200 of forming the first light emitting element LD1, process S300 of forming a base capping layer, process S400 of forming a base encapsulation layer, process S500 of etching at least a portion of the first light emitting element LD1, at least a portion of the base capping layer, and at least a portion of the base encapsulation layer, and process S600 of forming the second light emitting element LD2. Although not illustrated in FIG. 11, the method of fabricating the display device 100 may further include, after process S600 of forming the second light emitting element LD2, the process of forming a base capping layer, the process of forming a base encapsulation layer, the process of etching at least a portion of the second light emitting element LD2, at least a portion of the base capping layer, and at least a portion of the base encapsulation layer, the process of forming the third light emitting element LD3, the process of forming a base encapsulation layer, and the process of etching at least a portion of the third light emitting element LD3 and at least a portion of the base encapsulation layer.

Referring to FIG. 11 in conjunction with FIGS. 6 and 8, at process S100 of fabricating the pixel circuit layer PCL on the substrate SUB, circuit elements may be patterned on the substrate SUB, and the pixel circuit layer PCL may be provided.

In an embodiment, a conductive layer, an insulating layer, and the like on the substrate SUB may be formed based on a general process for fabricating a semiconductor device. In an embodiment, for example, the conductive layer or the insulating layer on the substrate SUB may be formed through a photolithography process, may be etched by various methods (e.g., wet etching, dry etching, or the like), and may be deposited by various methods (e.g., sputtering, chemical vapor deposition, or the like). However, the disclosure is not limited to a specific example.

At process S100, the transistors T_SP1 to T_SP3 may be patterned on the substrate SUB. Thereafter, the via layer VAL may be disposed on the pixel circuit layer PCL. Furthermore, in an embodiment, the first to third reflective electrodes may be patterned on the via layer VIAL. In an embodiment, the planarization layer may be formed on the via layer VIAL.

The method of fabricating the display device 100 may further include the process of forming the sidewalls SW and the pixel defining layer PDL. The method of fabricating the display device 100 may include the process of forming the anode electrodes AE for respectively forming the first to third light emitting elements LD1 to LD3. The anode electrodes AE may be formed by patterning before process S200 of forming the first light emitting element LD1.

Referring to FIG. 6, in an embodiment, the pixel defining layer PDL may be patterned after the anode electrodes AE are patterned on the via layer VIAL. The sidewalls SW may be patterned after the pixel defining layer PDL is patterned or during a process identical to the pixel defining layer PDL.

Referring to FIG. 8, in an embodiment, before the anode electrodes AE are formed, the sidewalls SW may be patterned. After the sidewalls SW are patterned, the anode electrodes AE may be patterned. After the anode electrodes AE are patterned, the pixel defining layer PDL may be patterned. In an embodiment, in the case where the sub-electrodes SBE are further located under the anode electrodes AE, the method of fabricating the display device 100 may further include the process of forming the sub-electrodes SBE.

Process S200 of forming the first light emitting element LD1 may include the process of forming the first emission structure EMS1 and the cathode electrode CE. The process of forming the light emitting elements LD in accordance with the disclosure may include process S200 of forming the first light emitting element LD1, process S600 of forming the second light emitting element LD2, and the process of forming the third light emitting element LD3. Process S200 of forming the first light emitting element LD1, process S600 of forming the second light emitting element LD2, and the process of forming the third light emitting element LD3 may be performed during different processes. Process S200 of forming the first light emitting element LD1, process S600 of forming the second light emitting element LD2, and the process of forming the third light emitting element LD3 may respectively include the process of forming the first emission structure EMS1, the process of forming the second emission structure EMS2, and the process of forming the third emission structure EMS3, and may each include the process of forming the cathode electrode CE. The process of forming the cathode electrode CE may be performed after each of the process of forming the first emission structure EMS1, the process of forming the second emission structure EMS2, and the process of forming the third emission structure EMS3.

At process S200 of forming the first light emitting element LD1, the first emission structure EMS1 and the cathode electrode CE may be deposited not only in the first sub-pixel area where the first sub-pixel SP1 is located but also in the second and third sub-pixel areas where the second and third sub-pixels SP2 and SP3 are respectively located. In an embodiment, for example, the first emission structure EMS1 and the cathode electrode CE may be deposited on the anode electrodes AE2 and AE3 located in the second and third sub-pixel areas, thereby covering the anode electrodes AE2 and AE3 located in the second and third sub-pixel areas. Thereafter, at least a portion of the cathode electrode CE formed at process S200 may be etched, thus forming the cathode electrode CE of the first light emitting element LD1.

Process S300 of forming the base capping layer may include the process of forming the base capping layer on the cathode electrode CE that overlaps the first emission structure EMS1. At process S300, the base capping layer may be deposited not only in the first sub-pixel area where the first sub-pixel SP1 is located but also in the second and third sub-pixel areas where the second and third sub-pixels SP2 and SP3 are respectively located. Subsequently, at least a portion of the base capping layer formed at process S300 may be etched, thus forming the first capping layer CPL1.

Process S400 of forming the base encapsulation layer may include forming the base encapsulation layer on the base capping layer. At process S400, the base encapsulation layer may be deposited not only in the first sub-pixel area where the first sub-pixel SP1 is located but also in the second and third sub-pixel areas where the second and third sub-pixels SP2 and SP3 are respectively located. Thereafter, at least a portion of the base encapsulation layer formed at process S400 may be etched, thus forming a portion of the encapsulation layer TFE.

Process S500 of etching at least a portion of the first light emitting element LD1, at least a portion of the base capping layer, and at least a portion of the base encapsulation layer may include the process of etching at least respective portions of the first light emitting element, the base capping layer, and the base encapsulation layer that are located in the second sub-pixel area and the third sub-pixel area.

At process S500, a photoresist which covers the first light emitting element LD1, the base capping layer, and the base encapsulation layer may be provided. The photoresist provided at process S500 allows the first light emitting element LD1, the base capping layer, and the base encapsulation layer that are located in the second and third sub-pixel areas to be exposed. Accordingly, at least a portion of the first light emitting element LD1, at least a portion of the base capping layer, and at least a portion of the base encapsulation layer that are located in the second and third sub-pixel areas may be etched.

At process S500, the anode electrodes AE2 and AE3 that are located in the second sub-pixel area and the third sub-pixel area may be exposed by etching the emission structure EMS1 and the cathode electrode CE of the first light emitting element LD1, the base capping layer, and the base encapsulation layer that are located in the second sub-pixel area and the third sub-pixel area.

Process S600 of forming the second light emitting element LD2 may be performed after process S500 of etching at least a portion of the first light emitting element, at least a portion of the base capping layer, and at least a portion of the base encapsulation layer.

As such, process S200 of forming the first light emitting element LD1 and process S600 of forming the second light emitting element LD2 may be performed through different processes. In an embodiment, for example, the first to third emission structures EMS1 to EMS3 may be respectively formed through different processes. In an embodiment, for example, the first emission structure EMS1 may be formed at process S200 of forming the first light emitting element LD1. The second emission structure EMS2 may be formed at process S600 of forming the second light emitting element LD2. The third emission structure EMS3 may be formed at process of forming the third light emitting element. In an embodiment, for example, portions of the cathode electrode CE that respectively form the first to third emission structures EMS1 to EMS3 may be formed through different processes. In an embodiment, for example, the portion of the cathode electrode CE that forms the first light emitting element LD1 may be formed at process S200 of forming the first light emitting element LD1. The portion of the cathode electrode CE that forms the second light emitting element LD2 may be formed at process S600 of forming the second light emitting element LD2. The portion of the cathode electrode CE that forms the third light emitting element LD3 may be formed at the process of forming the third light emitting element.

After process S600 of forming the second light emitting element LD2, the process of forming the base capping layer, the process of forming the base encapsulation layer, and the process of etching at least a portion of the second light emitting element LD2, at least a portion of the base capping layer, and at least a portion of the base encapsulation layer may be performed. A portion of the base capping layer that is formed at the process of forming the base capping layer after process S600 of forming the second light emitting element LD2 may form the second capping layer CPL2.

As such, the first capping layer CPL1 and the second capping layer CPL2 may be formed through different processes. In an embodiment, for example, the first capping layer CPL1 may be formed between process S200 of forming the first light emitting element LD1 and process S300 of forming the second light emitting element LD2. The second capping layer CPL2 may be formed between second S200 of forming the second light emitting element LD2 and the process of forming the third light emitting element LD3.

The display device 100 in accordance with an embodiment may not include the third capping layer. After the process of forming the third light emitting element LD3, the process of forming the base capping layer may not be performed. In other words, an embodiment of the method of fabricating the display device 100 may include the process of forming the capping layer CPL on only one or two of the first light emitting element LD1, the second light emitting element LD2, and the third light emitting element LD3. Therefore, the capping layer CPL may not be formed in some sub-pixels. In an embodiment, for example, the capping layer CPL may be formed to overlap only one or two of the first light emitting element LD1, the second light emitting element LD2, and the third light emitting element LD3. The process of forming the base capping layer may be omitted between some processes, thereby reducing the number of processes for fabricating the display device 100, and simplifying the process of fabricating the display device 100.

The process of etching at least a portion of the second light emitting element LD2, at least a portion of the base capping layer, and at least a portion of the base encapsulation layer may include the process of etching at least respective portions of the second light emitting element LD2, the base capping layer, and the base encapsulation layer that are located in the first sub-pixel area and the third sub-pixel area. The process of etching at least a portion of the third light emitting element LD3 and at least a portion of the base encapsulation layer may include the process of etching at least respective portions of the third light emitting element LD3 and the base encapsulation layer that are located in the first sub-pixel area and the third sub-pixel area.

Accordingly, with reference to FIGS. 3, 6, and 8, in an area where the first sub-pixel SP1 is located, the first emission area EMA1 and the first emission structure EMS1 may overlap each other, and the first emission area EMA1 may overlap neither the second emission structure EMS2 nor the third emission structure EMS3. In an area where the second sub-pixel SP2 is located, the second emission area EMA2 and the second emission structure EMS2 may overlap each other, and the second emission area EMA2 may overlap neither the first emission structure EMS1 nor the third emission structure EMS3. In an area where the third sub-pixel SP3 is located, the third emission area EMA3 and the third emission structure EMS3 may overlap each other, and the third emission area EMA3 may overlap neither the first emission structure EMS1 nor the second emission structure EMS2.

In an embodiment, after the encapsulation layer TFE is formed, the color filter layer CFL, the optical functional layer OFL, the overcoat layer OC, and the cover window CW may be placed, thereby providing the display device 100 in accordance with an embodiment.

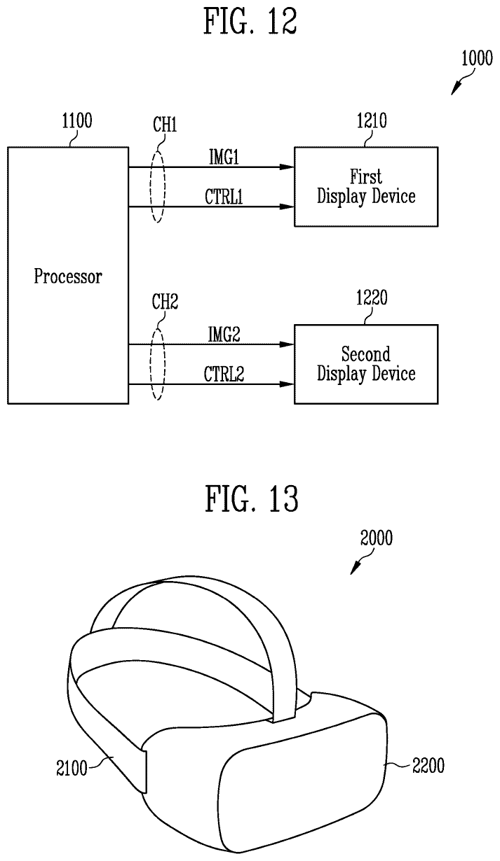

FIG. 12 is a block diagram illustrating an embodiment of a display system 1000.

Referring to FIG. 12, an embodiment of the display system 1000 may include a processor 1100, and one or more display devices 1210 and 1220.

The processor 1100 may perform various tasks and operations. In embodiments, the processor 1100 may include an application processor, a graphic processor, a microprocessor, a central processing unit (CPU), or the like. The processor 1100 may be connected to other components of the display system 1000 through a bus system to control the components.

FIG. 12 illustrates an embodiment where the display system 1000 includes the first and second display devices 1210 and 1220. The processor 1100 may be connected to the first display device 1210 through a first channel CH1, and may be connected to the second display device 1220 through a second channel CH2.

The processor 1100 may transmit first image data IMG1 and a first control signal CTRL1 to the first display device 1210 through the first channel CH1. The first display device 1210 may display an image based on the first image data IMG1 and the first control signal CTRL1. The first display device 1210 may be configured in a same manner as the display device 100 described with reference to FIG. 1.

The processor 1100 may transmit second image data IMG2 and a second control signal CTRL2 to the second display device 1220 through the second channel CH2. The second display device 1220 may display an image based on the second image data IMG2 and the second control signal CTRL2. The first display device 1220 may be configured in a same manner as the display device 100 described with reference to FIG. 1.

The display system 1000 may include computing systems that provide an image display function, such as a portable computer, a mobile phone, a smart phone, a tablet personal computer (PC), a smart watch, a watch phone, a portable multimedia player, a navigation system, and an ultra mobile personal computer (UMPC). Furthermore, the display system 1000 may include at least one of a head mounted display (HMD), a virtual reality (VR) device, a mixed reality (MR) device, or an augmented reality (AR) device.

FIG. 13 is a perspective diagram illustrating an application example of the display system 1000 of FIG. 12.

Referring to FIG. 13, in an embodiment, the display system 1000 of FIG. 12 may be applied to a head-mounted display device 2000. The head-mounted display device 2000 may be a wearable electronic device, which can be worn on the head of the user.

The head-mounted display 2000 may include a head-mounted band 2100 and a display device reception casing 2200. The head-mounted band 2100 may be connected to the display device reception casing 2200. The head-mounted band 2100 may include a horizontal band and/or a vertical band to fasten the head-mounted display 2000 to the head of the user. The horizontal band may enclose the sides of the head of the user, and the vertical band may enclose the top of the head of the user. However, the embodiments are not limited to the aforementioned example. In an embodiment, for example, the head-mounted band 2100 may be implemented in the form of eyeglass frames, a helmet, and so on.

The display device reception casing 2200 may receive the first and second display devices 1210 and 1220 of FIG. 12. The display device reception casing 2200 may further receive the processor 1100 of FIG. 12.

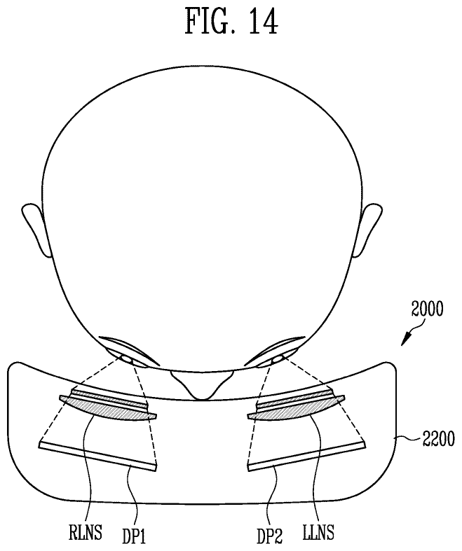

FIG. 14 is a diagram illustrating a head-mounted display device 2000 of FIG. 13 that is worn on a user.

Referring to FIG. 14, the first display panel DP1 of the first display device 1210 and the second display panel DP2 of the second display device 1220 are provided in the head-mounted display device 2000. The head-mounted display device 2000 may further include one or more lenses LLNS and RLNS.

In the display device reception casing 2200, the right-eye lens RLNS may be positioned between the first display panel DP1 and the right eye of the user. In the display device reception casing 2200, the left-eye lens LLNS may be positioned between the second display panel DP2 and the left eye of the user.

An image outputted from the first display panel DP1 can be viewed by the right eye of the user through the right-eye lens RLNS. The right lens RLNS may refract light emitted from the first display panel DP1 toward the right eye of the user. The right-eye lens RLNS may perform an optical function to adjust a viewing distance between the first display panel DP1 and the right eye of the user.

An image outputted from the second display panel DP2 can be viewed by the left eye of the user through the left-eye lens LLNS. The left lens LLNS may refract light emitted from the second display panel DP2 toward the left eye of the user. The left-eye lens LLNS may perform an optical function to adjust a viewing distance between the second display panel DP2 and the left eye of the user.

In embodiments, each of the right-eye lens RLNS and the left-eye lens LLNS may include an optical lens having a pancake-shaped cross-section. In embodiments, each of the right-eye lens RLNS and the left-eye lens LLNS may include a multi-channel lens including sub-areas having different optical characteristics. In such embodiments, each display panel may output images which respectively correspond to sub-areas of the multi-channel lens. The output images may be viewed to the user through the corresponding sub-areas.

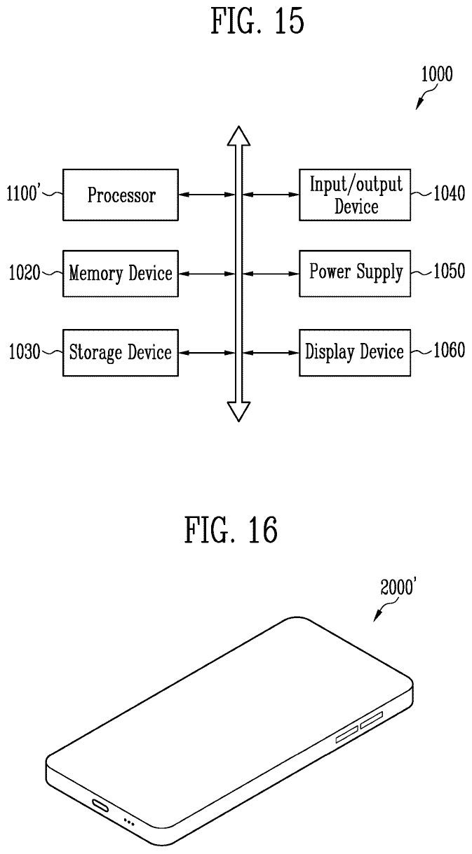

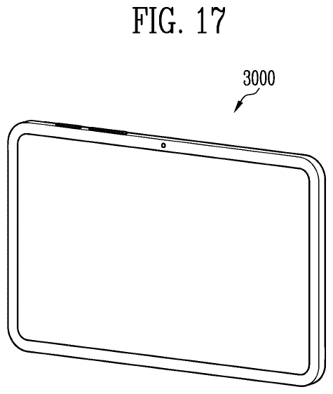

FIG. 15 is a block diagram illustrating an embodiment of a display system 1000 including the display device of FIG. 1. FIG. 16 is a perspective view illustrating an example of a smartphone 2000′ which can be implemented using the display system 1000 of FIG. 15. FIG. 17 is a perspective view illustrating an example of a tablet computer 3000 which can be implemented using the display system 1000 of FIG. 15.

Referring to FIG. 15, an embodiment of the display system 1000 may include a processor 1100′, a memory device 1020, a storage device 1030, an input/output (I/O) device 1040, a power supply 1050, and a display device 1060.

In an embodiment, as illustrated in FIG. 16, the display system 1000 may be implemented as a smartphone 2000′. In other embodiments, as illustrated in FIG. 17, the display system 1000 may be implemented as a tablet computer 3000. However, the aforementioned examples are illustrative, and the display system 1000 is not limited to the aforementioned examples. In an embodiment, for example, the display system 1000 may include a computing device or an electronic device which includes the display device 1060, such as a digital television (TV), a three-dimensional (3D) TV, a PC, a home appliance, a laptop computer, a mobile phone, a video phone, a smartpad, a smartwatch, a head-mounted display device, a personal digital assistant (PDA), a potable multimedia player (PMP), a digital camera, a music player, a portable game console, or a navigation device.

The processor 1100′ may perform various tasks and operations. In embodiments, the processor 1100′ may include an application processor, a graphic processing unit, a microprocessor, a central processing unit (CPU), or the like. The processor 1100′ may be connected to other components of the display system 1000 through a bus system. In an embodiment, the bus system may include a peripheral component interconnect (PCI) bus. The processor 1100′ may provide the display device 1060 with a data stream to be displayed on the display device 1060.

The data stream may be provided to the display device 100 of FIG. 1 as input image data. The processor 1100′ may further transmit a control signal to the display device 100.

The memory device 1020 may be provided as a working memory and/or a buffer memory of the electronic device 1000 and/or the processor 1100′. In an embodiment, the memory device 1020 may include volatile memory devices, such as a dynamic random access memory (DRAM), a static random access memory (SRAM), and a mobile DRAM.

The storage device 1030 may store data under the control of the processor 1100′. The storage device 1030 may include a nonvolatile storage medium which stores data even when the power of the display system 1000 is turned off. In an embodiment, the storage device 1030 may include a solid state drive (SSD), a hard disk drive (HDD), or the like.

The I/O device 1040 may include user input devices, such as a keyboard, a keypad, a touchpad, a touch screen, and a mouse, and output devices, such as a speaker and a printer.

The power supply 1050 may supply power needed to perform the operation of the display system 1000. In an embodiment, for example, the power supply 1050 may be a power management integrated circuit (PMIC). In an embodiment, for example, the power supply 1050 may include a battery.

The display device 1060 may display an image under the control of the processor 1100′. The display device 1060 may be connected to other components of the display system 1000 through a bus system and/or other communication links. The display device 1060 may be implemented as the display device 100 of FIG. 1. The display device 1060 may display images on the pixels PXL.

Various embodiments of the disclosure may provide a display device with improved light efficiency and lifespan, a display device including the display device, and a method of fabricating the display device.

Various embodiments of the disclosure is directed to a method of fabricating a display device capable of facilitating a fabrication process.

Although certain embodiments and implementations have been described herein, other embodiments and modifications will be apparent from the foregoing description. Accordingly, the concepts of the disclosure are not limited to the foregoing embodiments, but rather to the broader scope of the presented claims and various obvious modifications and equivalent arrangements.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device, comprising:
a substrate on which a first sub-pixel, a second sub-pixel, and a third sub-pixel are defined;
sidewalls disposed on the substrate;
an anode electrode disposed on the substrate to correspond to each of the first sub-pixel, the second sub-pixel, and the third sub-pixel;
a first emission structure disposed on the anode electrode of the first sub-pixel;
a second emission structure disposed on the anode electrode of the second sub-pixel;
a third emission structure disposed on the anode electrode of the third sub-pixel;
and a cathode electrode disposed on each of the first emission structure, the second emission structure, and the third emission structure,
wherein each of the sidewalls comprises:
a first sidewall; and
a second sidewall disposed on the first sidewall, and having a width greater than a width of the first sidewall.

2. The display device according to claim 1, further comprising
a capping layer disposed on the cathode electrode; and
a pixel defining layer disposed under the sidewalls,
wherein the capping layer does not overlap at least one selected from the first emission structure, the second emission structure, and the third emission structure in a plan view,
wherein the pixel defining layer exposes at least a portion of the anode electrode, and
wherein the sidewalls are respectively located in areas between the first emission structure, the second emission structure, and the third emission structure.

3. The display device according to claim 1, further comprising
a capping layer disposed on the cathode electrode,
wherein the capping layer does not overlap at least one selected from the first emission structure, the second emission structure, and the third emission structure in a plan view, and
wherein the anode electrode is disposed on the sidewalls.

4. The display device according to claim 3, further comprising
a pixel defining layer which encloses sides of the anode electrode,
wherein the pixel defining layer is disposed on the second sidewall, and
wherein the anode electrode has a surface area smaller than a surface area of the second sidewall in the plan view.

5. The display device according to claim 3,
wherein the cathode electrode comprises:
a first cathode electrode which contacts the first emission structure, the second emission structure, and the third emission structure; and
a second cathode electrode disposed on the first cathode electrode.

6. The display device according to claim 5,
wherein the second cathode electrode includes a transparent conductive oxide, and
wherein the second cathode electrode encloses the second sidewall.

7. The display device according to claim 5,
wherein the capping layer has a first transmittance and a first refractive index with respect to light in a visible light range,
wherein the second cathode electrode has a second transmittance and a second refractive index with respect to the light in the visible light range,
wherein the first transmittance is in a range from 0.9 times to 1.1 times the second transmittance, and
wherein the first refractive index is in a range from 0.9 times to 1.1 times the second refractive index.

8. The display device according to claim 5,
wherein the capping layer does not overlap one of the first emission structure, the second emission structure, and the third emission structure in the plan view, and overlaps remaining two of the first emission structure, the second emission structure, and the third emission structure in the plan view.

9. The display device according to claim 5,
wherein the capping layer does not overlap two of the first emission structure, the second emission structure, and the third emission structure in the plan view, and overlaps a remaining one of the first emission structure, the second emission structure, and the third emission structure in the plan view.

10. The display device according to claim 3, further comprising an encapsulation layer disposed on the capping layer, wherein the capping layer contacts the encapsulation layer.

11. The display device according to claim 3,
wherein the first sub-pixel provides light in a wavelength range from about 600 nm to about 750 nm,
wherein the second sub-pixel provides light in a wavelength range from about nm to about 560 nm,
wherein the third sub-pixel provides light in a wavelength range from about 370 nm to about 460 nm,
wherein, in the plan view, the capping layer overlaps the first emission structure and the second emission structure, and does not overlap the third emission structure, and
wherein each of the first emission structure, the second emission structure, and the third emission structure includes an organic emission material.

12. The display device according to claim 1,
wherein the cathode electrode comprises:
a first cathode electrode which contacts the first emission structure, the second emission structure, and the third emission structure; and
a second cathode electrode disposed on the first cathode electrode, and
wherein portions of the second cathode electrode, which respectively overlap the first emission structure, the second emission structure and the third emission structure, have different thicknesses from each other.

13. The display device according to claim 12, further comprising
an encapsulation layer disposed on the second cathode electrode,
wherein the second cathode electrode contacts the encapsulation layer.

14. The display device according to claim 13, further comprising a pixel defining layer disposed under the sidewalls,
wherein the pixel defining layer exposes at least a portion of the anode electrode, and
wherein the sidewalls are respectively located in areas between the first emission structure, the second emission structure, and the third emission structure.

15. The display device according to claim 13, further comprising
a pixel defining layer which encloses sides the anode electrode,
wherein the anode electrode and the pixel defining layer are disposed on the second sidewall, and
wherein the anode electrode has a surface area smaller than a surface area of the second sidewall in a plan view.

16. A method of fabricating a display device, the method comprising:
forming sidewalls on a substrate on which a first sub-pixel area, a second sub-pixel area, and a third sub-pixel area are defined;
forming a first light emitting element on the substrate in the first sub-pixel area;
forming a second light emitting element on the substrate in the second sub-pixel area;
forming a third light emitting element on the substrate in the third sub-pixel area; and
forming a capping layer on at least one selected from the first light emitting element, the second light emitting element, and the third light emitting element,
wherein the forming the first light emitting element comprises forming a first emission structure,
wherein the forming the second light emitting element comprises forming a second emission structure,
wherein the forming the third light emitting element comprises forming a third emission structure,
wherein the first emission structure, the second emission structure, and the third emission structure are respectively formed through different processes,
wherein each of the sidewalls comprises:
a first sidewall; and
a second sidewall disposed on the first sidewall, and having a width greater than a width of the first sidewall, and
wherein the capping layer overlaps the at least one selected from of the first light emitting element, the second light emitting element, and the third light emitting element in a plan view.

17. The method according to claim 16,
wherein each of the forming the first light emitting element, the forming the second light emitting element, and the forming the third light emitting element comprises forming a cathode electrode,
wherein the cathode electrode comprises:
a first cathode electrode which contacts the first emission structure, the second emission structure, and the third emission structure; and
a second cathode electrode disposed on the first cathode electrode, and
wherein, in the plan view, the capping layer overlaps one or two of the first emission structure, the second emission structure, and the third emission structure.

18. The method according to claim 17, further comprising:
forming anode electrodes on the substrate,
wherein the anode electrodes are disposed on the sidewalls.

19. A display system comprising:
a processor; and
a display device including pixels, wherein the display device displays images on the pixels under control of the processor,
wherein the display device comprises:
a substrate on which a first sub-pixel, a second sub-pixel, and a third sub-pixel are defined;
sidewalls disposed on the substrate;
an anode electrode disposed on the substrate to correspond to each of the first sub-pixel, the second sub-pixel, and the third sub-pixel;
a first emission structure disposed on the anode electrode of the first sub-pixel;
a second emission structure disposed on the anode electrode of the second sub-pixel;
a third emission structure disposed on the anode electrode of the third sub-pixel; anda cathode electrode disposed on each of the first emission structure, the second emission structure, and the third emission structure,
wherein each of the sidewalls comprises:
a first sidewall; and
a second sidewall disposed on the first sidewall, and having a width greater than a width of the first sidewall.

20. The display system according to claim 19,
wherein the cathode electrode comprises:
a first cathode electrode which contacts the first emission structure, the second emission structure, and the third emission structure; and
a second cathode electrode disposed on the first cathode electrode, and
wherein portions of the second cathode electrode, which respectively overlap the first emission structure, the second emission structure, and the third emission structure, have different thicknesses from each other.
